(19) United States
(12) Patent Application Publication
(10) Pub. No.: US 2024/0301551 A1
(43) Pub. Date: Sep. 12, 2024

(54) DEPOSITION APPARATUS AND DEPOSITION METHOD

(71) Applicant: Tokyo Electron Limited, Tokyo (JP)

(72) Inventor: Hiroki MURAKAMI, Yamanashi (JP)

(21) Appl. No.: 18/583,059

(22) Filed: Feb. 21, 2024

(30) Foreign Application Priority Data
Mar. 6, 2023 (JP) 2023-033815

(51) Int. Cl. C23C 16/455; C23C 16/458; C23C 16/52

(52) U.S. Cl. CPC C23C 16/45527; C23C 16/4557; C23C 16/45574; C23C 16/458; C23C 16/52

(57) ABSTRACT

A deposition apparatus includes a processing chamber; a substrate holder configured to hold a substrate in the processing chamber; a gas supply configured to supply a processing gas and a purge gas into the processing chamber; and a controller configured to control operation of the gas supply. The gas supply includes a gas supply nozzle configured to supply the purge gas into the processing chamber. The gas supply nozzle includes a heating mechanism configured to heat the purge gas. The controller is configured to, in supplying the purge gas into the processing chamber, operate the heating mechanism to heat the purge gas to be discharged from the gas supply nozzle.

### CROSS-REFERENCE TO RELATED APPLICATIONS

This application is based on and claims priority to Japanese Patent Application No. 2023-033815, filed on Mar. 6, 2023, the entire contents of which are incorporated herein by reference.

### BACKGROUND OF THE INVENTION

### 1. Field of the Invention

The disclosure herein relates to a deposition apparatus and a deposition method.

### 2. Description of the Related Art

In deposition by an atomic layer deposition (ALD) method, in general, the higher the deposition temperature in a processing chamber is, the more processing gases such as a source gas and a reaction gas are activated and the more the quality of a film stacked on a substrate increases. However, in a deposition apparatus, if the heat amount of the entire processing chamber is increased in order to improve the film quality, the manufacturing cost and the thermal budget of the substrate are increased.

Japanese Patent No. 5017913 describes a technology by which a processing gas is pre-heated in a processing gas supply nozzle, and the processing gas is activated in a processing chamber.

### SUMMARY OF THE INVENTION

According to one aspect of the present disclosure, a deposition apparatus includes a processing chamber; a substrate holder configured to hold a substrate in the processing chamber; a gas supply configured to supply a processing gas and a purge gas into the processing chamber; and a controller configured to control operation of the gas supply. The gas supply includes a gas supply nozzle configured to supply the purge gas into the processing chamber. The gas supply nozzle includes a heating mechanism configured to heat the purge gas. The controller is configured to, in supplying the purge gas into the processing chamber, operate the heating mechanism to heat the purge gas to be discharged from the gas supply nozzle.

### BRIEF DESCRIPTION OF THE DRAWINGS

Other objects and further features of the present invention will be apparent from the following detailed description when read in conjunction with the accompanying drawings, in which:

FIG. 1 is a cross-sectional view schematically illustrating a deposition apparatus according to an embodiment;

FIG. 2 is a cross-sectional view of a first gas supply nozzle of a gas supply;

FIG. 3A is a timing chart illustrating a deposition method according to a first example;

FIG. 3B is a timing chart illustrating a deposition method according to a second example;

FIG. 4A is a timing chart illustrating a deposition method according to a third example;

FIG. 4B is a timing chart illustrating a deposition method according to a fourth example;

FIG. 5 is a timing chart illustrating a deposition method according to a fifth example; and

FIG. 6 is a graph illustrating etching amounts when films deposited by the deposition methods according to the embodiment are wet etched.

### DESCRIPTION OF THE EMBODIMENTS

In the following, embodiments of the present disclosure will be described with reference to the accompanying drawings. In the accompanying drawings, the same components are denoted by the same reference numerals and the description thereof may be omitted.

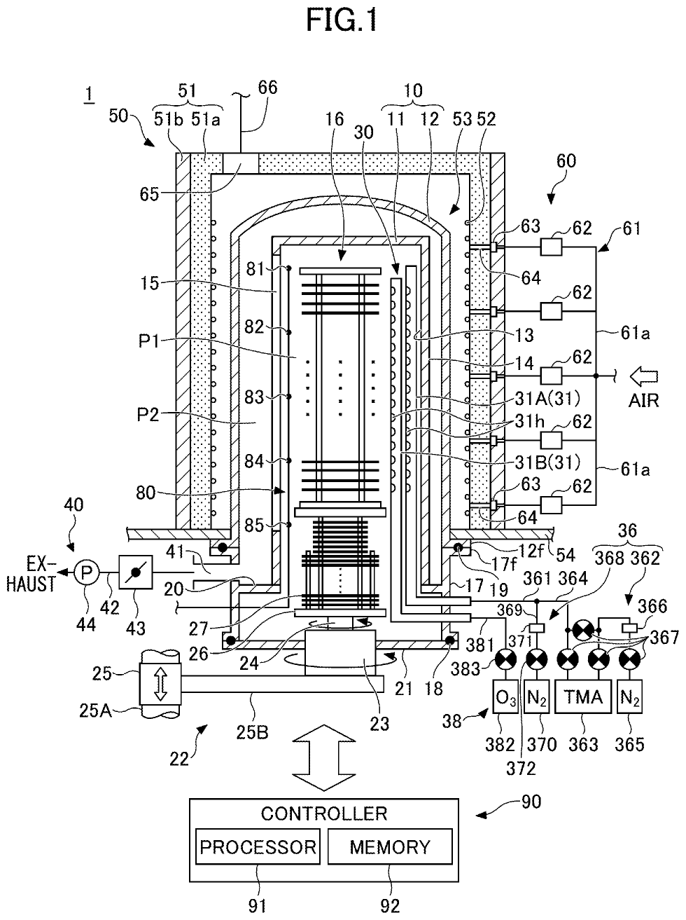

FIG. 1 is a cross-sectional view schematically illustrating a deposition apparatus 1 according to an embodiment. As illustrated in FIG. 1, the deposition apparatus 1 is configured as a vertical substrate processing apparatus (heat treatment apparatus) configured to accommodate and arrange a plurality of substrates W in the vertical direction, and deposit a desired film on the surface of each of the substrates W by an atomic layer deposition (ALD) method. The substrates W to be subjected to deposition are not particularly limited, and may be, for example, semiconductor substrates such as silicon wafers, compound semiconductor wafers, or the like, or glass substrates.

The deposition apparatus 1 includes a processing chamber 10 in which the substrates W are accommodated and deposition is performed; a gas supply 30 configured to supply a gas into the processing chamber 10; a gas exhaust 40 configured to exhaust the gas from the inside of the processing chamber 10; and a temperature adjustment furnace 50 disposed around the processing chamber 10. Further, the deposition apparatus 1 includes a controller 90 configured to control components of the deposition apparatus 1.

The processing chamber 10 is formed in a cylindrical shape and is installed such that the axis of the processing chamber 10 extends along the vertical direction (up-down direction). The processing chamber 10 has a double cylinder structure including an inner cylinder 11 and an outer cylinder 12 that accommodates the inner cylinder 11. The inner cylinder 11 and the outer cylinder 12 are formed of a heat-resistant material such as quartz or the like, and are arranged coaxially. The structure of the processing chamber 10 is not limited to the double cylinder structure, and may be a single cylinder structure or a multiple structure including three or more cylinders.

The inner cylinder 11 has an open lower end and a ceiling wall at the upper end thereof. Further, the inner cylinder 11 has an inner diameter greater than the diameter of each of the substrates W, and has an axial length greater than the range in which the substrates W are arranged in the vertical direction. The inside of the inner cylinder 11 serves as a processing space P1 in which deposition is performed by supplying the gas to each of the accommodated substrates W. The inner cylinder 11 has an opening 15 at a predetermined position along the circumferential direction of the inner cylinder 11. The opening 15 allows the gas to flow out from the processing space P1 into a flow space P2 located between the inner cylinder 11 and the outer cylinder 12. For example, the length of the opening 15 in the vertical direction is set to be greater than or equal to the range in which the substrates W are arranged in the vertical direction. The position where the opening 15 is formed is not particularly limited, and the opening 15 may be formed in the ceiling wall of the inner cylinder 11, for example.

Further, the inner cylinder 11 includes an accommodating section 13 at a position along the circumferential direction of the inner cylinder 11 and opposite to the opening 15. The accommodating section 13 communicates with the processing space P1, and can accommodate a gas supply nozzle 31 of the gas supply 30. The accommodating section 13 extends parallel to the (vertical) axis of the inner cylinder 11. As an example, the accommodating section 13 is provided on the inner side of a protruding portion 14 that protrudes radially outward from a portion of the side wall of the inner cylinder 11.

The outer cylinder 12 has an inner diameter greater than that of the inner cylinder 11, and covers the inner cylinder 11 in a non-contact manner. The flow space P2 formed inside the outer cylinder 12 is continuous along the upper surface and the side surfaces of the inner cylinder 11, and allows the gas flowing out from the opening 15 to flow vertically downward.

The lower end of the processing chamber 10 is supported by a cylindrical manifold 17 that is formed of stainless steel. The manifold 17 includes a manifold-side flange 17f at the upper end thereof. The manifold-side flange 17f fixes and supports an outer-cylinder-side flange 12f that is formed at the lower end of the outer cylinder 12. A seal member 19 is provided between the outer-cylinder-side flange 12f and the manifold-side flange 17f, so as to airtightly seal the outer cylinder 12 and the manifold 17. Further, the manifold 17 includes an annular support plate 20 on the inner wall of an upper portion thereof. The support plate 20 protrudes radially inward from the inner wall of the upper portion of the manifold 17, and fixes and supports the lower end of the inner cylinder 11.

A lid 21 of a substrate placement unit 22 is detachably attached to an opening at the lower end of the manifold 17. The manifold 17 includes a seal member 18 at the lower end thereof. The seal member 18 airtightly closes the opening at the lower end of the manifold 17 upon the lid 21 contacting the seal member 18.

A wafer boat 16 extends upward from the lid 21 of the substrate placement unit 22 in the vertical direction. The wafer boat 16 has a plurality of shelves (not illustrated) along the vertical direction, and is configured to hold the substrates W at predetermined intervals in the vertical direction. The substrates W are supported in the horizontal direction while being held by the wafer boat 16.

Further, the substrate placement unit 22 includes a rotation mechanism 23 configured to rotatably support the wafer boat 16, and a lifting mechanism 25 configured to support the rotation mechanism 23. The rotation mechanism 23 is provided at the center of the lid 21, and includes a rotation source (not illustrated) and a rotation shaft 24 rotated by the rotation source. A rotation plate 26 and a heat insulation unit 27 are coupled to the upper end of the rotation shaft 24. The wafer boat 16 rotates accompanying the rotation of the rotation shaft 24.

The lifting mechanism 25 includes a columnar part 25A extending in the vertical direction, and an arm 25B configured to be lifted and lowered relative to the columnar part 25A. The arm 25B extends substantially in the horizontal direction, and supports the rotation mechanism 23 and the wafer boat 16. The deposition apparatus 1 causes the lid 21 and the wafer boat 16 to move up and down integrally with each other by lifting and lowering the arm 25B of the lifting mechanism 25, so that the wafer boat 16 is inserted into and removed from the processing chamber 10.

The gas supply 30 includes one or more gas supply nozzles 31 to supply gases to the substrates W in the processing space P1 of the processing chamber 10. Examples of the gases supplied from the gas supply 30 include a source gas for depositing precursors on the substrates W, a reaction gas that reacts with the precursors, and a purge gas for purging the inside of the processing space P1. For example, if alumina (Al₂O₃) is deposited on the substrates W, an aluminum-containing gas such as trimethylaluminum (TMA) may be used as the source gas, and an oxygen-containing gas such as ozone (O₃) may be used as the reactant gas. If a silicon oxide film is deposited, a silicon-containing gas such as dichlorosilane (DCS) may be used as the source gas, and an oxygen-containing gas such as ozone may be used as the reaction gas. If a silicon nitride film is deposited, a silicon-containing gas may be used as the source gas, and a nitrogen-containing gas such as ammonia may be used as the reaction gas. If any other metal film is deposited, it is needless to say that a gas containing a target metal can be used as the source gas, and an appropriate reaction gas that reacts with the source gas can be used.

Examples of the purge gas used to deposit alumina, a silicon oxide film, or a silicon nitride film include inert gases such as nitrogen gas (N₂) and argon gas (Ar). In the following, the configuration of each component and the operation of the deposition apparatus 1 will be described by taking an example in which alumina in deposited on each of the substrates W.

In the present embodiment, the gas supply 30 includes two gas supply nozzles 31 (a first gas supply nozzle 31A and a second gas supply nozzle 31B). The first gas supply nozzle 31A is a nozzle for supplying the source gas and the purge gas into the processing chamber 10. The second gas supply nozzle 31B is a nozzle for supplying the reaction gas into the processing chamber 10. The configuration of the gas supply 30 is not limited to this configuration, and may include, for example, (three or more) gas supply nozzles 31 for respective types of gases such as the source gas, the reaction gas, and the purge gas. Conversely, the gas supply 30 may be configured to supply the source gas, the reaction gas, and the purge gas through one gas supply nozzle 31.

Each of the gas supply nozzles 31 (the first gas supply nozzle 31A and the second gas supply nozzle 31B) is an injector pipe formed of quartz, and is fixed to the manifold 17. Further, each of the gas supply nozzles 31 extends in the vertical direction inside the inner cylinder 11, is bent into an L-shape at the lower end thereof, and passes through the manifold 17 from the inside to the outside of the manifold 17. Each of the gas supply nozzles 31 has a plurality of gas holes 31h at predetermined intervals along the vertical direction in the inner cylinder 11, and discharges gases in the horizontal direction through the gas holes 31h. The intervals at which the gas holes 31h are arranged are set to be the same as the intervals at which the substrates W are supported by the wafer boat 16. Further, the vertical position of each of the gas holes 31h is set to be located at an intermediate position between adjacent ones of the substrates W in the vertical direction. Accordingly, the gas holes 31h can cause the gases to smoothly flow through spaces between the substrates W.

The first gas supply nozzle 31A according to the present embodiment has a function to pre-heat the source gas and the purge gas to be discharged into the processing chamber 10. The second gas supply nozzle 31B according to the present embodiment does not pre-heat the reaction gas to be discharged into the processing chamber 10. However, the deposition apparatus 1 may have a function to heat the reaction gas before discharging the reaction gas into the processing chamber 10. In this case, the second gas supply nozzle 31B may be configured in the same manner as the first gas supply nozzle 31A.

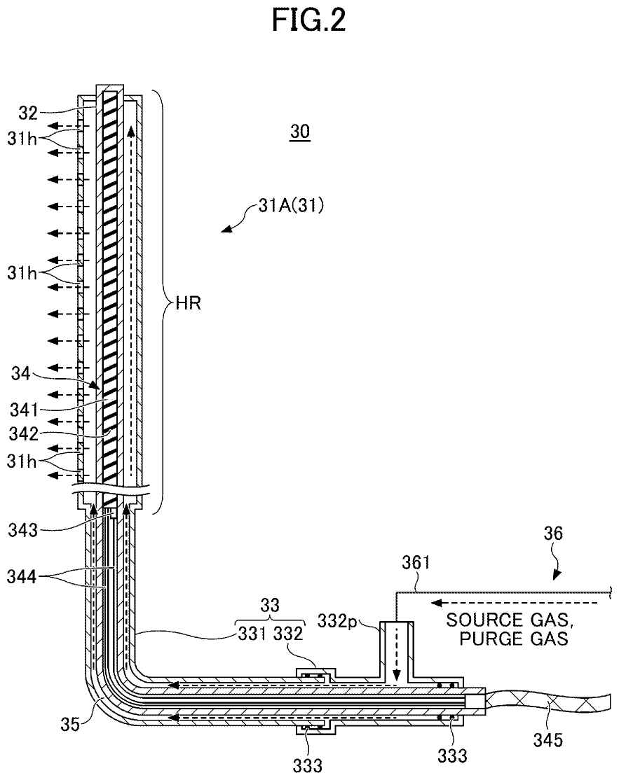

FIG. 2 is a cross-sectional view of the first gas supply nozzle 31A of the gas supply 30. As illustrated in FIG. 2, the first gas supply nozzle 31A has a double tube structure including an inner tube 32 and an outer tube 33. The inner tube 32 has a heating mechanism 34, and the outer tube 33 accommodates the inner tube 32 and causes the source gas and the purge gas to flow therethrough. The configuration of the first gas supply nozzle 31A is not particularly limited as long as the first gas supply nozzle 31A has a function to heat the gases. The first gas supply nozzle 31A may have a single tube structure or a structure including three or more tubes.

The inner tube 32 and the outer tube 33 are each formed as a hard tube made of a heat-resistant material such as quartz, and are arranged coaxially. The inner tube 32 and the outer tube 33 may be formed of materials different from each other. For example, the inner tube 32 may be formed of a material having a thermal conductivity higher than that of the outer tube 33.

The inner tube 32 extends inside the outer tube 33, and is fixed to the outer tube 33 at the distal end (the upper end in the vertical direction). The inner tube 32 accommodates the heating mechanism 34 in the inner space. In order to increase the heat transfer property of the inner tube 32, the thickness of the inner tube 32 may be smaller than the thickness of the outer tube 33.

The heating mechanism 34 includes an alumina core 341, a heating wire 342, a temperature sensor 343, and a plurality of wiring lines 344 connected to the heating wire 342 and the temperature sensor 343. The heating mechanism 34 includes a cover 345 that covers the plurality of wiring lines 344 at a position outward of the proximal end of the inner tube 32 so as to block high-frequency noise and the like.

The alumina core 341 and the heating wire 342 constitute a heating region HR of the heating mechanism 34. The alumina core 341 and the heating wire 342 are disposed at a position facing the plurality of gas holes 31h formed in the outer tube 33 of the first gas supply nozzle 31A. Specifically, the alumina core 341 and the heating wire 342 are provided over a range from the distal end of the inner tube 32 to below the lowermost gas hole 31h of the outer tube 33 in the vertical direction.

The alumina core 341 covers the entire inner wall of the inner tube 32 in the heating region HR. The heating wire 342 is held (embedded) inside the alumina core 341 or on the inner peripheral surface of the alumina core 341.

The heating wire 342 is connected to the plurality of wiring lines 344 at the lower end of the heating region HR, and is held by the alumina core 341 in an appropriate wiring pattern (for example, in a spiral pattern) extending vertically upward from the connection portion between the heating wire 342 and the plurality of wiring lines 344. Accordingly, the heating mechanism 34 can heat the entire heating region HR (alumina core 341) of the inner tube 32 substantially uniformly in response to electric power supply from the plurality of wiring lines 344 to the heating wire 342.

For example, the heating wire 342 is configured to adjust the temperature of the heating region HR in a range of approximately 0°° C. to 850° C. A set temperature at which the source gas and the purge gas are actually heated in the first gas supply nozzle 31A depends on the types of gases and the target temperature at which the substrates W are heated, but can be set to be in a range of approximately 600° C. to 700° C., for example.

Further, the temperature sensor 343 is installed at the lower end of the heating region HR, and measures the temperature of the heating region HR of the inner tube 32. Temperature information measured by the temperature sensor 343 is transmitted to the controller 90, and is used by the controller 90 to control the heating mechanism 34.

The outer tube 33 is formed so as to be thicker than the inner tube 32, and accommodates the inner tube 32. The first gas supply nozzle 31A has a gas flow channel 35 through which the source gas and the purge gas flow. The gas flow channel 35 is situated between the outer peripheral surface of the inner tube 32 and the inner peripheral surface of the outer tube 33. In order to maintain the shape of the gas flow channel 35, the first gas supply nozzle 31A may include, within the gas flow channel 35, one or more support frames (not illustrated) that are supported by the inner tube 32 and the outer tube 33.

The outer tube 33 includes a main tube 331 formed in an L shape and a joint tube 332 connected to a proximal end portion of the main tube 331 to introduce the source gas and the purge gas. The main tube 331 has the plurality of gas holes 31h at a portion thereof extending in the vertical direction. Further, a portion of the main tube 331 facing the heating region HR of the heating mechanism 34 has a diameter greater than the diameter of the other portion of the main tube 331 (a portion below the heating region HR). Accordingly, the main pipe 331 can stably discharge the gases from the gas holes 31h by suppressing an increase in the velocity of movement of the gases heated in the inner tube 32.

The joint tube 332 includes a port 332p connected to a first supply channel 361, and is formed in a T-shape. One end of the joint tube 332 is airtightly coupled to the proximal end portion of the main tube 331 via a seal 333. The other end of the joint tube 332 is airtightly coupled to a proximal end portion of the inner tube 32 via a seal 333.

Referring back to FIG. 1, the gas supply 30 includes a first supply 36 configured to supply the source gas and the purge gas into the above-described first gas supply nozzle 31A, and a second supply 38 configured to supply the reaction gas into the second gas supply nozzle 31B. The first supply 36 and the second supply 38 are provided outside the processing chamber 10. Further, the first supply 36 includes the first supply channel 361, a source gas supply mechanism 362, and a purge gas supply mechanism 368. The first supply channel 361 is connected to the first gas supply nozzle 31A, and the source gas supply mechanism 362 and the purge gas supply mechanism 368 are connected to the first supply channel 361.

The source gas supply mechanism 362 includes a source gas channel 364, a source gas source 363, a carrier gas source 365, a flow rate adjuster 366, and a plurality of valves 367. The source gas channel 364 is formed so as to extend from the carrier gas source 365 through the source gas source 363 to the first supply channel 361. The source gas source 363 stores the source gas (TMA gas). The carrier gas source 365 stores, as a carrier gas, an inert gas (N₂ gas) that is of the same type as the purge gas. The flow rate adjuster 366 is provided downstream of the carrier gas source 365, and adjusts the flow rate of the N₂ gas supplied from the carrier gas source 365. The plurality of valves 367 are provided at appropriate positions of the source gas channel 364, and open and close the flow channel of the source gas channel 364.

The purge gas supply mechanism 368 includes a purge gas channel 369, a purge gas source 370, a flow rate adjuster 371, and a valve 372. The purge gas channel 369 is formed so as to extend from the purge gas source 370 to the first supply channel 361. The purge gas source 370 stores the purge gas (N₂ gas). The flow rate adjuster 371 is provided downstream of the purge gas source 370, and adjusts the flow rate of the N₂ gas supplied from the purge gas source 370. The valve 372 is provided at an appropriate position of the purge gas channel 369, and switches between supply and stop of the supply of the N₂ gas by opening or closing the flow channel of the purge gas channel 369.

The second supply 38 includes a second supply channel 381, a reaction gas source 382, and a valve 383. The reaction gas source 382 can employ an appropriate configuration in accordance with the reaction gas to be supplied. For example, if O₃ gas is supplied as the reaction gas, an ozone generation apparatus can be employed. The valve 383 switches between supply and stop of the supply of the O₃ gas by opening or closing the flow channel of the second supply channel 381. The second supply 38 may include a flow rate adjuster (not illustrated) in the second supply channel 381.

The gas exhaust 40 exhausts gases from the inside of the processing chamber 10 to the outside. The gases supplied from the gas supply nozzle 31 flow from the processing space P1 of the inner cylinder 11 into the flow space P2, and are then exhausted through a gas outlet 41. The gas outlet 41 is formed in the upper side wall of the manifold 17 and is located above the support plate 20. An exhaust channel 42 of the gas exhaust 40 is connected to the gas outlet 41. The gas exhaust 40 includes a pressure adjustment valve 43 and a vacuum pump 44, in this order from the upstream side to the downstream side of the exhaust channel 42. The gas exhaust 40 adjusts the pressure in the processing chamber 10 by sucking the gases in the processing chamber 10 by the vacuum pump 44, and adjusting the flow rate of the gases to be exhausted by the pressure adjustment valve 43.

Further, a temperature sensor 80, configured to detect the temperature in the processing chamber 10, is provided inside the processing chamber 10 (for example, in the processing space P1 within the inner cylinder 11).

The temperature sensor 80 includes a plurality of (in the present embodiment, five) thermometers 81 to 85 located at different positions along the vertical direction. Thermocouples, resistance thermometer sensors, or the like can be used for the plurality of thermometers 81 to 85. The temperature sensor 80 transmits temperatures detected by the plurality of thermometers 81 to 85, respectively, to the controller 90.

The temperature adjustment furnace 50 covers the entire processing chamber 10, and is configured to heat and cool the substrates W accommodated in the processing chamber 10. Specifically, the temperature adjustment furnace 50 includes a cylindrical housing 51 having a ceiling, and a heater 52 provided on the inner side of the housing 51.

The housing 51 is attached to the upper surface of a base plate 54 located at the boundary between the processing chamber 10 and the manifold 17, such that the processing chamber 10 accommodated in the housing 51 is heated. The housing 51 is spaced apart from the processing chamber 10, and a temperature adjustment space 53 is formed between the processing chamber 10 and the housing 51.

The housing 51 includes a heat insulating part 51a having a ceiling and covering the entire processing chamber 10, and a reinforcing part 51b reinforcing the heat insulating part 51a at the outer periphery of the heat insulating part 51a. The heat insulating part 51a is formed of a material including, for example, silica, alumina, or the like as a main component thereof, and reduces heat transfer. The reinforcing part 51b is formed of a metal such as stainless steel or the like, for example. In addition, in order to reduce influence of heat on the outside of the temperature adjustment furnace 50, the outer periphery of the reinforcing part 51b is covered by a water cooling jacket (not illustrated).

The heater 52 of the temperature adjustment furnace 50 may have an appropriate configuration for heating the plurality of substrates W in the processing chamber 10. For example, an infrared heater that radiates infrared rays to heat the processing chamber 10 can be used as the heater 52. In this case, the heater 52 is formed in a line shape such as a spiral shape, an annular shape, an arc shape, a shank shape, a meandering shape, or the like, and is held on the inner peripheral surface of the heat insulating part 51a via a holder (not illustrated).

The target temperature at which the heater 52 of the temperature adjustment furnace 50 heats the substrates W depends on the type of a film to be deposited, but can be set to be in a range of approximately 200° C. to 400° C., for example. That is, a temperature at which the heating mechanism 34 of the gas supply 30 heats the source gas and the purge gas is preferably set to be in a range of 1.5 times to 3.5 times the target temperature at which the substrates W are heated by the temperature adjustment furnace 50. Accordingly, the deposition apparatus 1 can satisfactorily activate the source gas and the purge gas before the source gas and the purge gas are discharged from the first gas supply nozzle 31A.

Further, the temperature adjustment furnace 50 include a cooling section 60 configured to cause a cooling gas such as air to flow through the temperature adjustment space 53 in order to cool the processing chamber 10 during or after deposition. The cooling section 60 includes an external supply channel 61, flow rate adjusters 62, supply channels 63, and supply holes 64. The external supply channel 61 and the flow rate adjusters 62 are provided outside the temperature adjustment furnace 50, the supply channels 63 are provided in the reinforcing part 51b, and the supply holes 64 are provided in the heat insulating part 51a.

The external supply channel 61 is connected to a blower (not illustrated), and includes a plurality of branch channels 61a at intermediate positions thereof. The flow rate adjusters 62 are provided with respect to the branch channels 61a, and are configured to adjust the flow rate of air flowing through the branch channels 61a.

The plurality of supply channels 63 are formed at respective positions along the axial direction of the reinforcing part 51b (that is, along the vertical direction). Each of the plurality of supply channels 63 extends annularly in the cylindrical reinforcing part 51b along the circumferential direction in a planar cross-sectional view.

The supply holes 64 are formed in a matrix along the axial direction and the circumferential direction of the heat insulating part 51a. The supply holes 64 arranged along the axial direction are located at the same axial positions as the supply channels 63 arranged along the axial direction, and communicate with the respective supply channels 63 along the horizontal direction. The supply holes 64 are formed so as to penetrate the heat insulating part 51a, and eject the air introduced into the supply channels 63 toward the temperature adjustment space 53.

Further, the cooling section 60 has an exhaust hole 65 in the ceiling of the housing 51. The exhaust hole 65 discharges the air supplied into the temperature adjustment space 53. The exhaust hole 65 is connected to an external exhaust channel 66 provided outside the housing 51.

A computer including a processor 91, a memory 92, an input/output interface (not illustrated), and the like can be used for the controller 90 of the deposition apparatus 1. The processor 91 is one of or a combination of a central processing unit (CPU), a graphics processing unit (GPU), an application-specific integrated circuit (ASIC), a field-programmable gate array (FPGA), a circuit including a plurality of discrete semiconductors, and the like. The memory 92 is an appropriate combination of a volatile memory and a nonvolatile memory (for example, a compact disc, a digital versatile disc (DVD), a hard disk, a flash memory, or the like).

The memory 92 stores programs for operating the deposition apparatus 1, and recipes, such as process conditions or the like for deposition. The processor 91 performs a deposition method in the deposition apparatus 1 by reading and executing the programs and the recipes stored in the memory 92. The controller 90 may be configured with a host computer or a plurality of client computers that communicate information via a network.

In a deposition method, the controller 90 causes the temperature adjustment furnace 50 to control the supply of gas by the gas supply 30 and the exhaust of the gas by the gas exhaust 40, while adjusting the temperature of each of the substrates W inside the processing chamber 10. In particular, the deposition apparatus 1 according to the present embodiment improves the quality of a film deposited on each of the substrates W by causing the controller 90 to appropriately control the order of supplying gases (the source gas, the reaction gas, and the purge gas) from the gas supply 30, the supply amounts, the temperatures, and the like. In the following, some examples of deposition methods according to the present embodiment will be described.

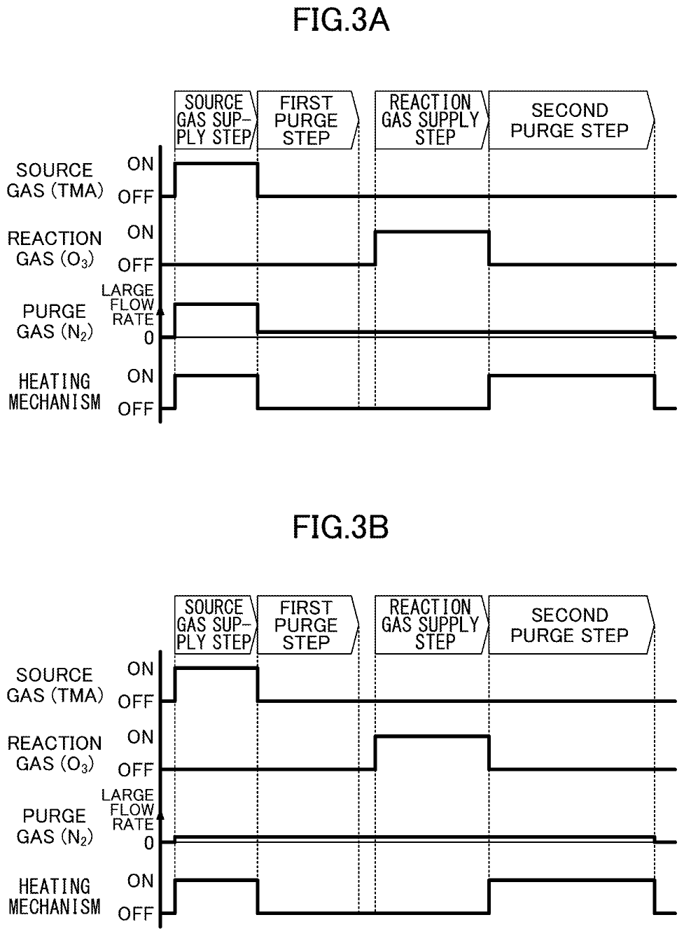

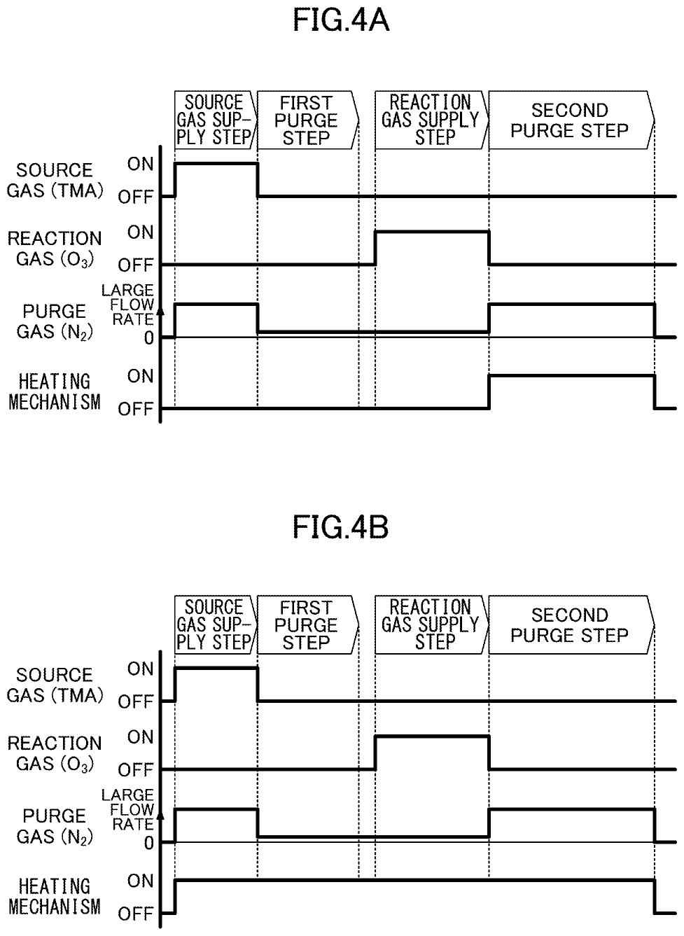

FIG. 3A is a timing chart illustrating a deposition method according to a first example. FIG. 3B is a timing chart illustrating a deposition method according to a second example. FIG. 4A is a timing chart illustrating a deposition method according to a third example. FIG. 4B is a timing chart illustrating a deposition method according to a fourth example. FIG. 5 is a timing chart illustrating a deposition method according to a fifth example.

In each of the deposition methods, the controller 90 performs a source gas supply step (step (A)), a first purge step (step (B)), a reaction gas supply step (step (C)), and a second purge step (step (D)) in this order by controlling the operation of the gas supply 30. Further, while performing (the source gas supply step, the first purge step, the reaction gas supply step, and the second purge step in) each of the deposition methods, the controller 90 operates the temperature adjustment furnace 50 to adjust the temperature of each of substrates W. The target temperature of the temperature adjustment furnace 50 is set to an appropriate temperature value in the range of 200° C. to 400° C. as described above. Further, the controller 90 maintains the internal pressure of the processing chamber 10 at a target pressure by operating the gas exhaust 40 to exhaust gases from the inside of the processing chamber 10 while performing each of the deposition methods.

In the source gas supply step, the controller 90 controls the first supply 36 to supply TMA gas, which is the source gas, from the first gas supply nozzle 31A into the processing space P1. The source gas supply mechanism 362 of the first supply 36 conveys the TMA gas while supplying N₂ gas (the carrier gas) as described above. The flow rate of the TMA gas at this time is set to, for example, 0.5 slm. In the source gas supply step of the deposition method according to the first example, the controller 90 operates the purge gas supply mechanism 368 to supply N₂ gas, which is the purge gas, into the processing space P1 simultaneously with the TMA gas. The flow rate of the N₂ gas at this time is set to, for example, 50 slm. Therefore, in the source gas supply step illustrated in FIG. 3A, each of the TMA gas and the N₂ gas is in an ON state. In each of the timing charts illustrated in FIG. 3A to FIG. 5, for the purge gas, it is indicated that the higher in the vertical axis, the larger the flow rate.

Then, in the source gas supply step, the controller 90 operates the heating mechanism 34 to heat the heating region HR of the inner tube 32. The target temperature at which the heating mechanism 34 heats the gases in the heating region HR is set to an appropriate temperature value in the range of 600° C. to 700° C. as described above. Accordingly, both the TMA gas and the N₂ gas are heated in the first gas supply nozzle 31A, and are discharged into the processing space P1 in an activated state. The deposition apparatus 1 can adsorb the activated TMA gas onto the surface of each of the substrates W.

Next, in the first purge step, the controller 90 controls the first supply 36 to supply the N₂ gas from the first gas supply nozzle 31A into the processing space P1. In this case, the controller 90 causes the source gas supply mechanism 362 to stop the supply of the TMA gas, and causes the purge gas supply mechanism 368 to supply the N₂ gas only. The flow rate of the N₂ gas at this time is the same as the flow rate (50 slm) in the source gas supply step. Further, in the first purge step, the controller 90 stops the operation of the heating mechanism 34, and supplies the unheated N₂ gas into the processing space P1.

Then, the controller 90 performs the reaction gas supply step at a slight interval after the first purge step. The controller 90 controls the second supply 38 to supply O₃ gas, which is the reaction gas, from the second gas supply nozzle 31B into the processing space P1. The O₃ gas supplied from the second gas supply nozzle 31B reacts with the TMA gas adhering to the surface of each of the substrates W, thereby forming alumina (Al₂O₃) on the surface of each of the substrates W.

In the deposition method according to the first example, the purge gas supply mechanism 368 is operated even in the steps (the interval and the reaction gas supply step) after the first purge step, and the unheated N₂ gas (the purge gas) is supplied from the first gas supply nozzle 31A at a flow rate lower than that in the first purge step. The flow rate of the N₂ gas at this time is, for example, 5 slm.

In the final second purge step, the controller 90 operates the first supply 36 to supply the N₂ gas from the first gas supply nozzle 31A into the processing space P1. The flow rate of the N₂ gas at this time is the same as the flow rate (5 slm) in the reaction gas supply step. However, the controller 90 operates the heating mechanism 34 to heat the N₂ gas in the first gas supply nozzle 31A, and discharges the N₂ gas in an activated state into the processing space P1. The deposition apparatus 1 can satisfactorily purge reaction byproducts remaining on the surface of the substrate W by the activated N₂ gas.

As described above, in the deposition method according to the first example, in the source gas supply step and the second purge step in which the purge gas (N₂ gas) is supplied into the processing space P1, the purge gas to be discharged is heated. Accordingly, in the deposition method, reaction byproducts, generated while a film is deposited on each of the substrates W, can be effectively removed, and the quality of the deposited film can be improved. Moreover, in the source gas supply step, the source gas is also activated by being heated, and thus a large amount of the activated source gas can adhere to the surface of each of the substrates W.

Next, the deposition method according to the second example illustrated in FIG. 3B will be described. The deposition method according to the second example differs from the deposition method according to the first example in the flow rate of the purge gas in the source gas supply step. Specifically, the controller 90 controls the first supply 36 to supply TMA gas, which is the source gas, and N₂ gas, which is the purge gas, from the first gas supply nozzle 31A into the processing space P1. The flow rate of the N₂ gas at this time is set to, for example, 5 slm. Therefore, in the source gas supply step illustrated in FIG. 3B, the flow rate of the N₂ gas is lower than the flow rate of the N₂ gas illustrated in FIG. 3A.

However, in the source gas supply step, the controller 90 operates the heating mechanism 34 to heat both the TMA gas and the N₂ gas in the first gas supply nozzle 31A. Therefore, the deposition apparatus 1 can adsorb the activated TMA gas onto the surface of each of the substrates W. In addition, since the flow rate of the N₂ gas is low, the deposition apparatus 1 can remove reaction byproducts generated during the adsorption, while suppressing, as much as possible, inhibition of TMA adhesion due to the flow of the N₂ gas. The reaction gas supply step and the second purge step in the second example are performed in the same manner as those in the first example.

Next, the deposition method according to the third example illustrated in FIG. 4A will be described. The deposition method according to the third example differs from the deposition method according to the first example in that N₂ gas is heated only in the second purge step. That is, in the source gas supply step, the operation of the heating mechanism 34 is stopped, and unheated TMA gas and unheated N₂ gas are supplied into the processing space P1. The first purge step and the reaction gas supply step are controlled in the same manner as in the first example.

In the second purge step, the controller 90 causes the purge gas supply mechanism 368 to operate and supply the N₂ gas into the processing space P1 at a flow rate of 50 slm. In the second purge step, the heating mechanism 34 heats the N₂ gas in the first gas supply nozzle 31A, thereby activating the N₂ gas. In this case as well, the deposition apparatus 1 can satisfactorily remove reaction byproducts by the N₂ gas activated in the second purge step, and thus the film quality can be improved.

Next, the deposition method according to the fourth example illustrated in FIG. 4B will be described. In the deposition method according to the fourth example, N₂ gas (and TMA gas) are heated by the heating mechanism 34 throughout all the steps (the source gas supply step, the first purge step, the reaction gas supply step, and the second purge step). The flow rate of the N₂ gas in each of the steps is the same as the flow rate in the deposition method according to the third example.

The controller 90 constantly heats the first gas supply nozzle 31A such that the TMA gas and the N₂ gas supplied from the first gas supply nozzle 31A can be activated at all times. Accordingly, the deposition apparatus 1 can prevent a delay in heating (insufficient heating or the like) of the gases in the first gas supply nozzle 31A at the start or the end of the heating, and can stably supply the activated gases. In addition, the activated N₂ gas can satisfactorily remove reaction byproducts. Next, the deposition method according to

the fifth example illustrated in FIG. 5 will be described. The deposition method according to the fifth example differs from the deposition methods according to the first example to the fourth example, in that the flow rate of N₂ gas is increased throughout all the steps and gases are heated by the heating mechanism 34 throughout all the steps. The flow rate of the N₂ gas can be set to, for example, 50 slm. That is, in the deposition method according to the fifth example, a large amount of the continuously-activated N₂ gas is continuously supplied into the processing space P1. Accordingly, in the reaction gas supply step, the deposition apparatus 1 can satisfactorily remove reaction byproducts and the like floating in the processing space P1 by the N₂ gas. As a result, the quality of a film deposited on each of the substrates W can be further improved.

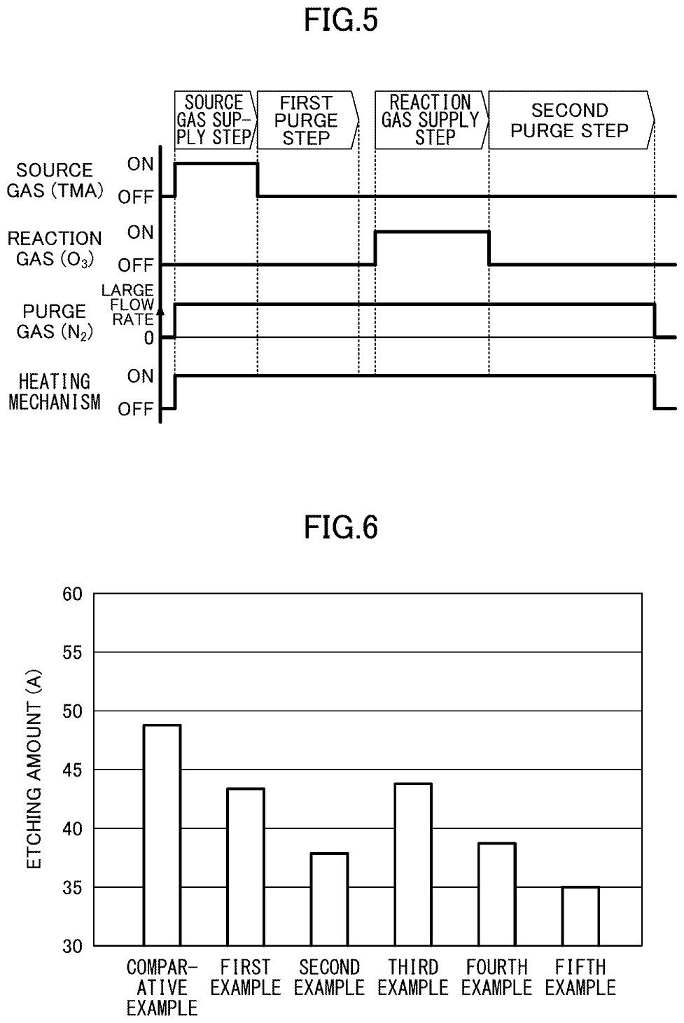

FIG. 6 is a graph illustrating etching amounts when films deposited by the deposition methods according to the embodiment are wet etched. In the deposition methods according to the embodiment, the temperature of each of the substrates W was controlled to be 300° C. by the temperature adjustment furnace 50, and the quality of films, deposited on the substrates W when the deposition methods according to the first example to the fifth example were performed without changing the temperature control by the temperature adjustment furnace 50, was evaluated. In the graph of FIG. 6, the leftmost bar indicates a comparative example illustrating an etching amount when the first gas supply nozzle 31A is not heated.

In the graph of FIG. 6, the vertical axis represents an etching amount when wet etching is performed. That is, if the etching amount in the wet etching is large, it means that a large amount of a film deposited on a substrate W is etched. In other words, if the etching amount is large, the durability of the deposited film is considered to be low (the deposited film is considered to be fragile), and the quality of the film is considered to be low.

As illustrated in FIG. 6, the etching amounts of films deposited by the deposition methods according to the first example to the fifth example were lower than the etching amount of a film deposited by a deposition method according to the comparative example in which the first gas supply nozzle 31A was not heated. Therefore, it can be considered that the quality of the films deposited on substrates W can be improved by performing the deposition methods according to the first example and the fifth example. In particular, the etching amount of a film deposited on a substrate W by the deposition method according to the fifth example was the smallest. This indicates that the quality of the film deposited on the substrate W can be further improved by supplying a large amount of activated (heated) N₂ gas into the processing chamber 10.

The technical ideas and effects of the present disclosure described in the above embodiment will be described below.

A first aspect of the present disclosure provides a deposition apparatus 1 including a processing chamber 10; a substrate holder (wafer boat 16) configured to hold a substrate W in the processing chamber 10; a gas supply 30 configured to supply a processing gas and a purge gas into the processing chamber 10; and a controller 90 configured to control operation of the gas supply 30, wherein the gas supply 30 includes a gas supply nozzle 31 configured to supply the purge gas into the processing chamber 10, the gas supply nozzle 31 includes a heating mechanism 34 configured to heat the purge gas, and the controller 90 is configured to, in supplying the purge gas into the processing chamber 10, operate the heating mechanism 34 to heat the purge gas to be discharged from the gas supply nozzle 31.

According to the above first aspect of the present disclosure, the deposition apparatus 1 can easily activate the purge gas by causing the heating mechanism 34 of the gas supply nozzle 31 to heat the The activated purge gas can effectively purge gas. remove reaction byproducts and the like present near the substrate W, and thus the quality of a film deposited on the substrate W can be further improved. In particular, as compared to a configuration in which the gas is heated from the outside of the processing chamber 10, the heating mechanism 34 can heat the gas directly. Accordingly, the deposition apparatus 1 can reduce electric power required to heat the purge gas, and can thus reduce the thermal budget of the substrate W and the manufacturing cost related to disposition.

Further, the processing gas includes a source gas that is adsorbed on the substrate W, and a reaction gas that reacts with the source gas, the gas supply nozzle 31 includes a first gas supply nozzle 31A configured to supply the purge gas together with the source gas, and a second gas supply nozzle 31B configured to supply the reaction gas, and the heating mechanism 34 is provided in the first gas supply nozzle 31A. Accordingly, the deposition apparatus 1 can heat the source gas together with the purge gas, and can cause the source gas activated in the processing chamber 10 to adhere to the substrate W.

Further, the substrate W includes a plurality of substrates W, the processing chamber 10 is configured to accommodate and arrange the plurality of substrates W in a vertical direction, the gas supply nozzle 31 has a plurality of gas holes 31h at a portion thereof extending in the vertical direction within the processing chamber 10, and the heating mechanism 34 is provided over a range from an uppermost gas hole 31h to a lowermost gas hole 31h of the plurality of gas holes 31h. Accordingly, the deposition apparatus 1 can heat the entire gas (purge gas) immediately before the gas is discharged from the gas holes 31h, and can supply the activated gas into the processing chamber 10.

The deposition apparatus 1 further includes a temperature adjustment furnace 50 disposed outside the processing chamber 10 and configured to adjust a temperature in the processing chamber 10, wherein the controller 90 is configured to heat the purge gas to be supplied from the gas supply nozzle 31 by setting a temperature at which the heating mechanism 34 heats the purge gas to be higher than the temperature in the processing chamber 10 adjusted by the temperature adjustment furnace 50. Accordingly, the deposition apparatus 1 can easily heat the gas by the heating mechanism 34, while reducing the heating cost of the temperature adjustment furnace 50 and the thermal budget of the substrate.

Further, the processing gas includes a source gas that is adsorbed on the substrate W, and a reaction gas that reacts with the source gas, and the controller 90 is configured to perform, in a following order,
(A) supplying the source gas into the processing chamber 10;
(B) supplying only the purge gas into the processing chamber 10 after (A);
(C) supplying the reaction gas into the processing chamber 10 after (B); and
(D) supplying only the purge gas into the processing chamber 10 after (C). Accordingly, the deposition apparatus 1 can satisfactorily deposit a desired film on the surface of the substrate W.

Further, in (A), the controller 90 is configured to cause the heating mechanism 34 to heat the source gas and the purge gas; and supply the source gas and the purge gas into the processing chamber 10. Accordingly, the deposition apparatus 1 can cause the source gas activated in the processing chamber 10 to adhere to the substrate W, and can satisfactorily remove reaction byproducts by the purge gas.

Further, in (D), the controller 90 is configured to cause the heating mechanism 34 to heat the purge gas; and supply the purge gas into the processing chamber 10. Accordingly, the deposition apparatus 1 can satisfactorily remove, by the activated purge gas, reaction byproducts generated as a result of the supply of the reaction gas.

Further, in (C), the controller 90 is configured to cause the heating mechanism 34 to heat the purge gas; and supply the purge gas into the processing chamber 10. Accordingly, when the reaction gas is supplied, the deposition apparatus 1 can supply the activated purge gas in addition to the reaction gas.

Further, throughout (A), (B), (C), and (D), the controller 90 is configured to cause the heating mechanism 34 to heat the purge gas; and supply the purge gas into the processing chamber 10. Accordingly, the deposition apparatus 1 can supply the activated purge gas while avoiding insufficient heating or the like at the start or the end of the heating of the purge gas.

Further, throughout (A), (B), (C), and (D), the controller 90 is configured to supply the purge gas into the processing chamber 10 at a same flow rate. Accordingly, the deposition apparatus 1 can stably supply the activated purge gas, and can further improve the quality of a film deposited on the substrate W.

Further, a second aspect of the present disclosure provides a deposition method performed by a deposition apparatus 1 including a processing chamber 10, a substrate holder (wafer boat 16) configured to hold a substrate W in the processing chamber 10, and a gas supply 30 configured to supply a processing gas and a purge gas into the processing chamber 10, wherein the gas supply 30 includes a gas supply nozzle 31 configured to supply the purge gas into the processing chamber 10, and the gas supply nozzle 31 includes a heating mechanism 34 configured to heat the purge gas. The deposition method includes, in supplying the purge gas into the processing chamber 10, operating the heating mechanism 34 to heat the purge gas to be discharged from the gas supply nozzle 31. The deposition apparatus 1 can further improve the film quality, while reducing the thermal budget of the substrate and the manufacturing cost related to deposition.

The deposition apparatus 1 and the deposition methods according to the embodiments disclosed herein are illustrative in all respects and are not restrictive. The embodiments can be modified and improved in various forms without departing from the scope and spirit of the appended claims. The matters described in the multiple embodiments can also take other configurations as long as there is no contradiction, and can be combined as long as there is no contradiction.

According to one aspect of the present disclosure, the film quality can be further improved while reducing the thermal budget of a substrate and the manufacturing cost related to disposition.

What is claimed is:

1. A deposition apparatus comprising:
a processing chamber;
a substrate holder configured to hold a substrate in the processing chamber;
a gas supply configured to supply a processing gas and a purge gas into the processing chamber; and
a controller configured to control operation of the gas supply,
wherein the gas supply includes a gas supply nozzle configured to supply the purge gas into the processing chamber,
the gas supply nozzle includes a heating mechanism configured to heat the purge gas, and
the controller is configured to, in supplying the purge gas into the processing chamber, operate the heating mechanism to heat the purge gas to be discharged from the gas supply nozzle.

2. The deposition apparatus according to claim 1, wherein the processing gas includes a source gas that is adsorbed on the substrate, and a reaction gas that reacts with the source gas,
the gas supply nozzle includes a first gas supply nozzle configured to supply the purge gas together with the source gas, and a second gas supply nozzle configured to supply the reaction gas, and
the heating mechanism is provided in the first gas supply nozzle.

3. The deposition apparatus according to claim 1, wherein the substrate includes a plurality of substrates,
the processing chamber is configured to accommodate and arrange the plurality of substrates in a vertical direction,
the gas supply nozzle has a plurality of gas holes at a portion thereof extending in the vertical direction within the processing chamber, and
the heating mechanism is provided over a range from an uppermost gas hole to a lowermost gas hole of the plurality of gas holes.

4. The deposition apparatus according to claim 1, further comprising a temperature adjustment furnace disposed outside the processing chamber and configured to adjust a temperature in the processing chamber,
wherein the controller is configured to heat the purge gas to be supplied from the gas supply nozzle by setting a temperature at which the heating mechanism heats the purge gas to be higher than the temperature in the processing chamber adjusted by the temperature adjustment furnace.

5. The deposition apparatus according to claim 1, wherein the processing gas includes a source gas that is adsorbed on the substrate, and a reaction gas that reacts with the source gas, and
the controller is configured to perform, in a following order,
(A) supplying the source gas into the processing chamber;
(B) supplying only the purge gas into the processing chamber after (A);
(C) supplying the reaction gas into the processing chamber after (B); and
(D) supplying only the purge gas into the processing chamber after (C).

6. The deposition apparatus according to claim 5, wherein, in (A), the controller is configured to:
cause the heating mechanism to heat the source gas and the purge gas; and
supply the source gas and the purge gas into the processing chamber.

7. The deposition apparatus according to claim 5, wherein, in (D), the controller is configured to:
cause the heating mechanism to heat the purge gas; and
supply the purge gas into the processing chamber.

8. The deposition apparatus according to claim 5, wherein, in (C), the controller is configured to:
cause the heating mechanism to heat the purge gas; and
supply the purge gas into the processing chamber.

9. The deposition apparatus according to claim 5, wherein, throughout (A), (B), (C), and (D), the controller is configured to:
cause the heating mechanism to heat the purge gas; and
supply the purge gas into the processing chamber.

10. The deposition apparatus according to claim 9, wherein, throughout (A), (B), (C), and (D), the controller is configured to supply the purge gas into the processing chamber at a same flow rate.

11. A deposition method performed by a deposition apparatus including
a processing chamber,
a substrate holder configured to hold a substrate in the processing chamber, and
a gas supply configured to supply a processing gas and a purge gas into the processing chamber,
wherein the gas supply includes a gas supply nozzle configured to supply the purge gas into the processing chamber, and
the gas supply nozzle includes a heating mechanism configured to heat the purge gas, the deposition method comprising:
in supplying the purge gas into the processing chamber, operating the heating mechanism to heat the purge gas to be discharged from the gas supply nozzle.
